(19) United States
(12) Patent Application Publication
(10) Pub. No.: US 2026/0268212 A1
(43) Pub. Date: Sep. 10, 2026

(54) METHODS OF TRAINING AND USING A MACHINE LEARNING MODEL FOR REDUCING READ ERRORS IN A MEMORY DEVICE

(71) Applicant: Microchip Technology Incorporated, Chandler, AZ (US)

(72) Inventors: Michele Cirella, Castelmassa (IT); Salvatrice Scommegna, Cornate D'Adda (IT); Pitamber Shukla, San Jose, CA (US); Antonio Aldarese, Vimercate (IT)

(73) Assignee: Microchip Technology Incorporated, Chandler, AZ (US)

(21) Appl. No.: 19/224,041

(22) Filed: May 30, 2025

Related U.S. Application Data
(60) Provisional application No. 63/768,014, filed on Mar. 6, 2025.

(51) Int. Cl. G06N 20/00; G11C 16/34

(52) U.S. Cl. CPC G06N 20/00; G11C 16/34

(57) ABSTRACT

A computer-implemented method for training a machine learning model comprises receiving a first dataset related to first threshold voltages and first read error totals for a first memory cell type of the memory device, the first memory cell type having a first data storage capacity; receiving a second dataset related to second threshold voltages and second read error totals for a second memory cell type of the memory device, the second memory cell type having a second data storage capacity which is greater than the first data storage capacity; and training the machine learning model based on the first dataset and the second dataset, the trained machine learning model being configured to determine the threshold voltage for use with one or more memory cell(s) of the second memory cell type based on input data from one or more memory cell(s) of the first memory cell type.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/768,014; titled “METHODS OF TRAINING AND USING A MACHINE LEARNING MODEL FOR REDUCING READ ERRORS IN A MEMORY DEVICE”; and filed Mar. 6, 2025. The Provisional Application is hereby incorporated by reference, in its entirety, into the current patent application.

### FIELD OF THE INVENTION

Various examples of the current technology relate to methods of training and using a machine learning model to determine a threshold voltage that is used to read data from a memory device.

### BACKGROUND OF THE INVENTION

Memory devices typically perform read operations using reference voltages corresponding to read voltage thresholds. The read voltage threshold may be a default, static read voltage threshold or may be a dynamic read voltage threshold. In the case of a dynamic read voltage threshold, algorithms such as background read positioning (BRP) and/or read retry (RR) may be utilized to determine a read voltage threshold that may reduce or minimize a number of read errors produced during read operations. These algorithms may utilize significant resources (e.g., time) to determine the read voltage threshold due to the number of read operations necessary to converge on the optimized read voltage threshold.

The background discussion is intended to provide information related to the present technology which is not necessarily prior art.

### SUMMARY OF THE INVENTION

Various examples of the current technology address one or more of the above-mentioned problems and provide a distinct advance in the art of training and using a machine learning model to determine a threshold voltage that is used to read data from a memory device in order to reduce a number of read errors that occur when reading data from the memory device. Specifically, the machine learning model is trained (offline) to develop a relationship regarding threshold voltages between a first type of data storage cells having a first capacity and a second type of data storage cells having a second capacity that is greater than the first capacity. During operation of the memory device, data regarding threshold voltages from the first type of data storage cells is input to the trained machine learning model, which determines the threshold voltage for reading data from the second type of data storage cells. The current technology provides benefit because background processes to determine the threshold voltage for the second type of data storage cells consume greater resources than the process of gathering threshold voltage data from the first type of data storage cells and using the machine learning model.

One example of the current technology provides a method for training the machine learning model. The method comprises receiving a first dataset related to first threshold voltages and first read error totals for a first memory cell type of the memory device, the first memory cell type having a first data storage capacity; receiving a second dataset related to second threshold voltages and second read error totals for a second memory cell type of the memory device, the second memory cell type having a second data storage capacity which is greater than the first data storage capacity; and training the machine learning model based on the first dataset and the second dataset, the trained machine learning model being configured to determine the threshold voltage for use with one or more memory cell(s) of the second memory cell type based on input data from one or more memory cell(s) of the first memory cell type.

Another example of the current technology provides a method for using the machine learning model. The method comprises determining a first vector of first threshold voltages and corresponding first read error totals for a first memory cell type of the memory device, the first memory cell type having a first capacity; inputting the first vector into the machine learning model to generate a plurality of predicted second read error totals for a second memory cell type, the second memory cell type having a second capacity which is greater than the first capacity; determining a read threshold voltage corresponding to a minimum of the predicted second read error totals; and performing a read operation in the memory device on one or more memory cell(s) of the second memory cell type using the read threshold voltage.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic block diagram of a host system and a data storage system, each constructed in accordance with various examples of the current technology, one or both of which being configured to utilize a machine learning model to reduce a number of read errors in a memory device of the data storage system;

FIG. 2 illustrates an example computing system configured to perform operations in accordance with the various examples of the present disclosure;

FIG. 3A includes a schematic block diagram of a memory structure of the memory device and a plot of a number of cells versus threshold voltage for a page and a first reference of a single level cell (SLC) memory cell;

FIG. 3B includes a plot of a number of read error totals versus threshold voltage shift coefficients for the page of the first reference of the SLC memory cell;

FIG. 4A includes a schematic block diagram of a memory structure of the memory device and a plot of a number of cells versus threshold voltage for a plurality of pages, including an upper page, a middle page, and a lower page, and a plurality of references, including first through seventh references, of a triple level cell (TLC) memory cell;

FIG. 4B includes a plot of a number of read error totals versus threshold voltage shift coefficients for the upper page and seventh reference of the TLC memory cell;

FIG. 5 illustrates a plurality of blocks listing operations of a method for training a machine learning model to determine a threshold voltage used to read data from a memory device; and

FIG. 6 illustrates a plurality of blocks listing operations of a method for using a machine learning model to determine a threshold voltage and using the threshold voltage to read data from a memory device.

The drawing figures do not limit the current technology to the specific examples disclosed and described herein. The drawings are not necessarily to scale, emphasis instead being placed upon clearly illustrating the principles of the technology.

### DETAILED DESCRIPTION OF THE INVENTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

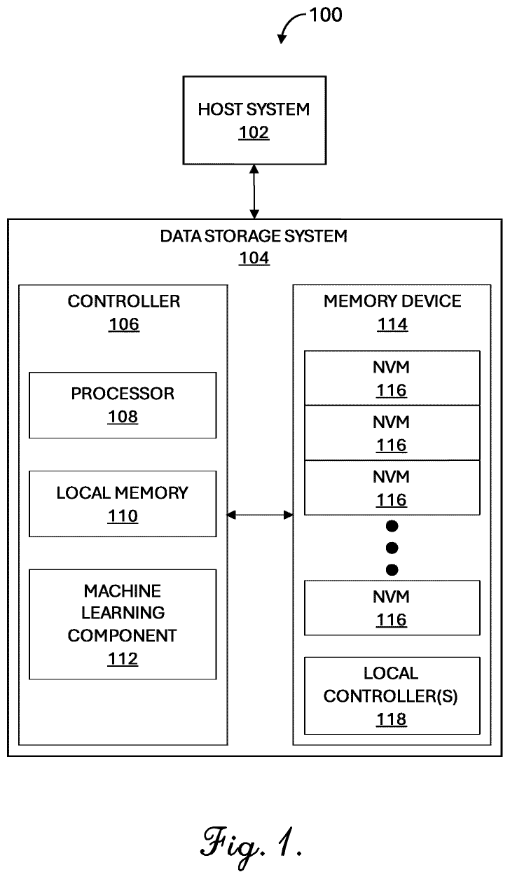

FIG. 1 illustrates an example system 100 including a host system 102 and a data storage system 104. The data storage system 104 may include a controller 106. The controller 106 may include a processor 108, a local memory 110, and a machine learning component 112. The data storage system 104 may also include a memory device 114. The memory device 114 may include a plurality of non-volatile memory (NVM) media 116 and one or more local controller(s) 118.

In various examples, a read or write request may be received from the host system 102 via a peripheral component interconnect express (PCIe) interface that connects the data storage system 104 to servers or CPUs. PCIe is a standardized interface for motherboard components. The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

The NVM media 116 further comprises one or more of a plurality of data cell, or memory cell, types-including a single level cell (SLC) memory cell configured to store one (1) bit of data, a multi level cell (MLC) memory cell configured to store two (2) bits of data, or a triple level cell (TLC) memory cell configured to store three (3) bits of data, or combinations thereof. The NVM media 116 may also or alternatively comprise a quad level cell (QLC) memory cell configured to store four (4) bits of data and a penta level cell (PLC) memory cell configured to store five (5) bits of data. In various examples, the NVM media 116 includes cells of two (2) or more cell types.

The machine learning component 112 is utilized to maintain efficient operation of the data storage system 104. Specifically, the machine learning component 112 is utilized to predict or determine a threshold voltage to be applied to a plurality of word lines of the NVM media 116 during data read operations such that a number of read errors is minimized. In various examples, the ML component 112 may include a ML model or ML engine (MLE) including, for example, an artificial neural network (ANN) with thirty-two (32) neurons, sixty-four (neurons), or more neurons, and two (2), four (4), or more hidden layers, without limitation. However, it is foreseen that the operations may be performed with other types of ML models without departing from the spirit of the present disclosure.

In various examples, a plurality of ML models may be stored on the local memory 110 or the ML component 112, or a combination thereof. The ML models may be trained during a manufacturing or offline stage, such that the ML component 112 may utilize any of the ML models during operation. The ML models may be trained by another computing device, such as a computing system 200 of the manufacturer. Each of the ML models may include one or more of a regression model, a decision tree model, a support vector machine (SVM) model, a clustering model, a convolutional neural network (CNN), a recurrent neural network (RNN), a generative adversarial network (GAN), or the like, or combinations thereof, without limitation. The ML models may be subject to supervised or unsupervised training or a combination thereof. The ML models may be trained during an offline process when the data storage system 104 is not performing normal operations. The ML models may be trained on data obtained from performing training read operations on a training device, which may include structures illustrated and described and illustrated throughout this disclosure and may be constructed to simulate conditions encountered during operation.

As discussed in more detail below, each ML model broadly receives data regarding read error measurements for memory cell type(s) having a lower storage capacity (e.g., SLC memory cell(s)), and generates read error predictions for memory cell type(s) having a higher storage capacity (e.g., TLC memory cell(s)). The predictions are used to select improved threshold voltages for read operations on the higher storage capacity cells. In various examples, a plurality of threshold voltages are selected. One or more ML models may be used for generating the predictions and/or selecting corresponding threshold voltages, without departing from the spirit of the present disclosure. For example, one of ordinary skill will appreciate that a single ML model, seven (7) separate ML models, and/or that any number of ML models therebetween may be trained to predict error totals and generate or select seven (7) corresponding threshold voltages. In various examples, a first ML model may predict error totals of a target vector corresponding to three (3) threshold voltages, while a second ML model may predict error totals of a target vector corresponding to four (4) other threshold voltages, such that the two (2) ML models together generate or support selection of seven (7) threshold voltages for performing read operations on TLC memory cell(s).

In various examples, instructions for executing the machine learning component 112 may be stored in the local memory 110. Some or all functions of the machine learning component 112 may be executed by the processor 108, the local controller(s) 118, other circuitry of the controller 106 or memory device 114, or combinations thereof.

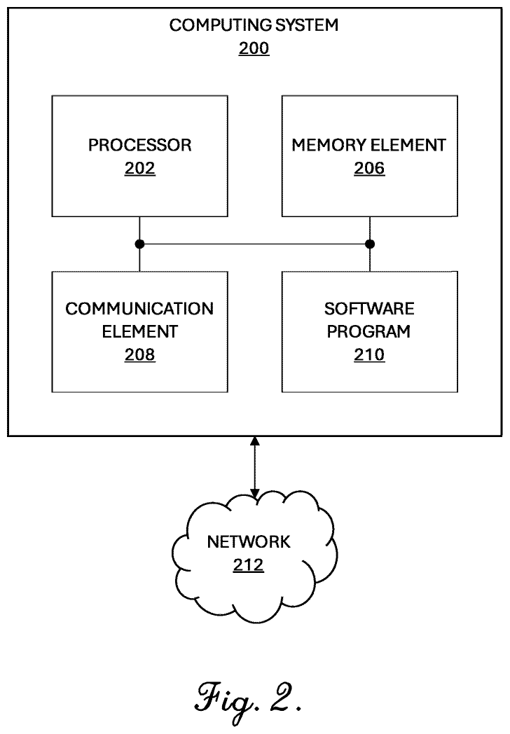

FIG. 2 illustrates a computing system 200 connected to a communication network 212. The computing system 200 may include at least one processor 202, at least one memory element 206, a communication element 208, and a software program 210. In various examples, the computing system 200 may be a host system (e.g. the host system 102 of FIG. 1) or a data storage system (e.g. the data storage system 104 of FIG. 1) or a combination thereof, without limitation.

The software program 210 may be configured with instructions for performing or enabling performance, or both, of at least some of the operations set forth herein. In an example, the software program 210 comprises instructions stored on computer-readable media of memory element 206. In various examples, the software program 210 may include instructions for performing operations of the machine learning component 112 discussed with reference to FIG. 1.

The communication network 212 generally allows communication between the computing system 200 and another computing device, such as between a remote host system (e.g. the host system 102), a local host system, a data storage system (e.g. the data storage system 104 of FIG. 1), or combinations thereof, without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include transmitter(s), receiver(s), or transceiver(s). The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals or data or both that comply with communication standards such as cellular 2G, 3G, 4G or 5G, Institute of Electrical and Electronics Engineers (IEEE) 802.11 standard such as WiFi, IEEE 802.16 standard such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain examples, the communication element 208 may also couple with optical fiber cables. The communication element 208 may respectively be in communication with the processor 202 or the memory element 206 or both.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some examples, the memory element 206 may be embedded in, or packaged in the same package as, the processor 202. The memory element 206 may include, or may constitute, a “computer-readable medium”. The memory element 206 may store the instructions, code, code segments, software, firmware, programs, applications, apps, services, daemons, or the like that are executed by the processor 202. In an example, the memory element 206 stores the software applications/program 210. The memory element 206 may also store settings, data, documents, sound files, photographs, movies, images, databases, and the like. In various examples, the memory element 206 may include a first memory component (e.g. the local memory 110 of FIG. 1) and one or more SSDs (e.g. the memory device 114 of FIG. 1).

The processor 202 may include electronic hardware components such as processors. The processor 202 may include digital processing unit(s). The processor 202 may include microprocessors (single-core and multi-core), microcontrollers, digital signal processors (DSPs), field-programmable gate arrays (FPGAs), analog application-specific integrated circuits (ASICs), digital ASICs, or the like, or combinations thereof. The processor 202 may generally execute, process, or run instructions, code, code segments, software, firmware, programs, applications, apps, processes, services, daemons, or the like. For instance, the processor 202 may execute the software applications/program 210. The processor 202 may also include hardware components such as finite-state machines, sequential and combinational logic, and other electronic circuits that can perform the functions necessary for the operation of the current disclosure. The processor 202 may be in communication with the other electronic components through serial or parallel links that include universal busses, address busses, data busses, control lines, and the like.

Through hardware, software, firmware, or various combinations thereof, the processor 202 may—alone or in combination with other processing elements—be configured to perform the operations of examples of the present disclosure. The examples described herein in connection with the attached drawing figures are intended to describe aspects of the disclosure in sufficient detail to enable those skilled in the art to practice the disclosure. Other examples can be utilized and changes can be made without departing from the scope of the present disclosure. The system may include additional, less, or alternate functionality, alternate device(s), or both, including those discussed elsewhere herein. The above detailed description is, therefore, not to be taken in a limiting sense. The scope of the present disclosure is defined only by the appended claims, along with the full scope of equivalents to which such claims are entitled, unless otherwise expressly stated, readily apparent, or expressly stated and readily apparent to those skilled in the art from the description.

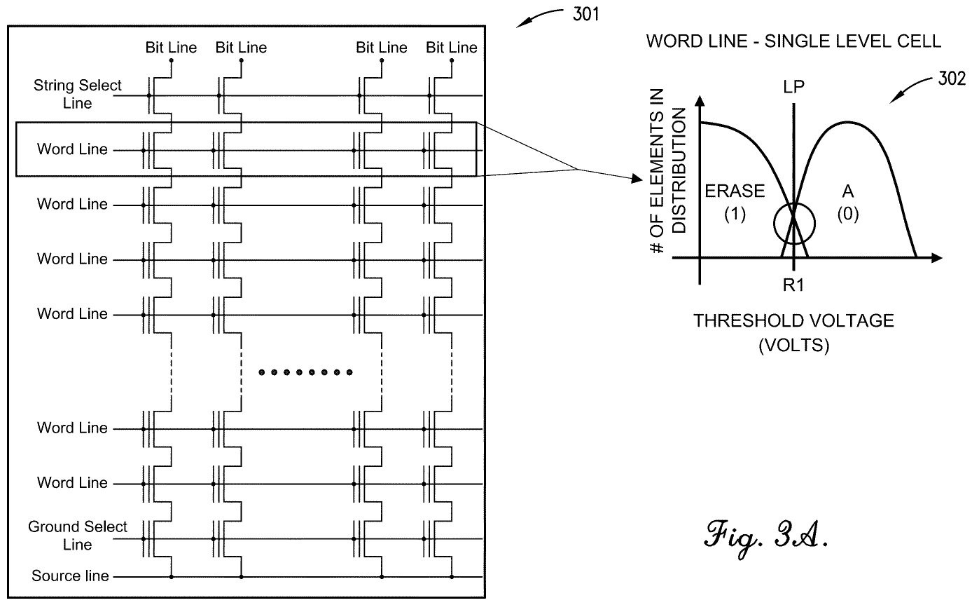

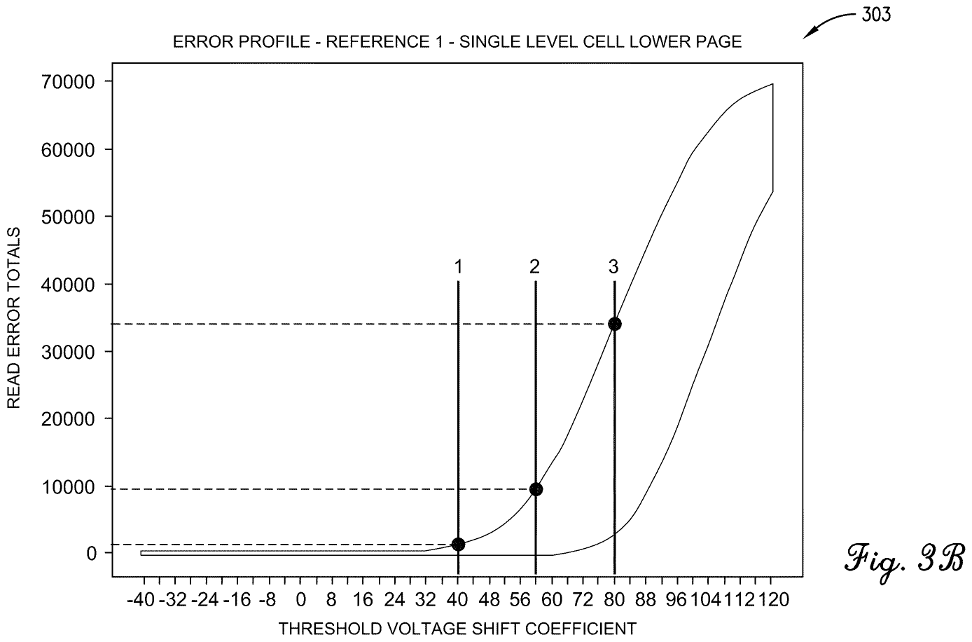

Additional structural information and performance data regarding SLC memory cells are shown in FIG. 3A. The example SLC memory cell stores one (1) bit of data which can have one (1) of two (2) values. To the left of the figure is a schematic structural diagram 301 of a block of one (1) NVM media 116. Generally, the NVM media 116 may include a plurality of word lines (WLs), wherein each WL is an electrical conductor that is electrically connected to control gates of the cells in a respective row of cells. (Each WL may be drawn as a horizontal line shown in the diagram 301.) Each WL has an electronic signal applied to it, that, according to a voltage level of the signal, selects a row (or page) of cells. When a specific WL is activated (e.g., when a read voltage is applied), the cells connected to that WL are selected for reading or writing. In NAND flash memory, cells are organized into a series of strings, with each string being connected to one of a plurality of bit lines (BL), wherein each BL is an electrical conductor that is electrically connected to the drains of cells in a column of cells. (Each BL may be drawn as a vertical line shown in the diagram 301.) In addition, each BL has an electronic signal applied to it, that, according to a voltage level of the signal, may enable data transfer to and from the cells of a selected WL during read and write operations. During a read operation, the voltage on the BL reflects a state of the selected cells (or page). Accordingly, the voltage, the current, or both on the BL may be measured, determined, or both to determine the value of the data in the selected cells.

Also, in the diagram 301, a plurality of SLC memory cells are bounded with a box. To the right in FIG. 3A is a first plot 302 of a number of elements in a distribution versus the threshold voltage applied to the word line for the plurality of SLC memory cells in a lower page (“LP”) position with a first reference (“R1”), wherein the plot 302 illustrates a distribution of threshold voltages according to the number of memory cells to which the word line is electrically connected. The plot 302 further shows one of a plurality of distributions for each state of the SLC, which has two (2) states including a first state, ERASE, and a second state, A. In general, a greater number of memory cells operates with a threshold voltage near the center of the distribution for each state, while a smaller number of cells may operate with a threshold voltage at either edge of the distribution.

Referring to FIG. 3B, a second plot 303 of a number of read error totals versus a threshold voltage shift coefficient for a plurality of SLC memory cells having reference R1 of the NVM media 116 is shown. The plot 303 includes a plurality of curved lines that when plotted on the same graph in combination form a variable width curve, the boundaries of which are outlined, although the individual curved lines are not shown. Each curved line represents a plot of a total number of read errors versus the threshold voltage shift coefficient, from which the threshold voltage is determined. The threshold voltage is applied to a respective one of a plurality of WLs, such as the WLs shown in the diagram 301, that is electrically connected to a plurality of SLC memory cells. The WLs and the SLC memory cells to which they are connected may include a plurality of pages positioned in a plurality of blocks and on a plurality of dies of memory storage.

The threshold voltage shift coefficient is a (unitless) coefficient that is multiplied by a shift value in order to determine an offset, in Volts (V) or milliVolts (mV), for the threshold voltage. That is, the offset may be determined by the equation: OFFSET=C×SV, wherein C is the threshold voltage shift coefficient that is one of the X-axis values in the plot 303, and SV is the shift value, which varies according to one or more aspects of the NVM media 116, such as type of memory cell. Examples of the values for the SV include 12.5 mV and 25 mV. As an example of determining the offset for the threshold voltage, if the threshold voltage shift coefficient is eight (8) and the SV is 12.5 mV (for the current type of memory cell), then the offset is equal to 100 mV or 0.1 V. The offset is added to (if positive), or subtracted from (if negative), the present threshold voltage being applied to one or more WL(s). As a further example, if the present threshold voltage is three (3) V, then, in order to determine the read error totals for the threshold voltage shift coefficient of eight (8), the threshold voltage applied to the one or more WL(s) is 3 V+0.1 V=3.1 V.

The data shown in the plot 303 is created by applying a voltage source, i.e., a power supply, to each of the plurality of WLs. The voltage applied to each WL may be swept, or varied, from a first threshold voltage to a second threshold voltage. For example, as shown in FIG. 3B, the voltage applied to each WL is swept from the first threshold voltage to the second threshold voltage using a threshold voltage shift coefficient that varies from approximately −40 to approximately 120, or vice versa. At a certain increment of the threshold voltage shift coefficient, say approximately two (2) or four (4), the total number of read errors for each WL is recorded. Given that the NVM media 116 may comprise hundreds or thousands of WLs, for each increment of the threshold voltage shift coefficient, a total of hundreds or thousands of read errors may be recorded. Over a first range of threshold voltage shift coefficients, such as from approximately −40 to approximately 32, there is little variability in the read error totals recorded across the different WLs. Over a second range of threshold voltage shift coefficients, such as from approximately 32 to approximately 120, the variability in the read error totals recorded across the different WLs increases which gives the curve of the displayed data its width. As an example, for a threshold voltage shift coefficient of approximately 60, the totals of the read errors range from approximately zero (0) to approximately 10,000 according to the page of the SLC memory cells to which a respective one of the WLs is connected. That is, one of the pages of SLC memory cells may yield a read error total of approximately zero (0), while another of the pages of SLC memory cells may yield a read error total of approximately 10,000.

The read error totals recorded may include a plurality of read disturb errors recorded during a plurality of program/erase (P/E) cycles, a plurality of data retention errors recorded during the plurality of P/E cycles, or a combination of both.

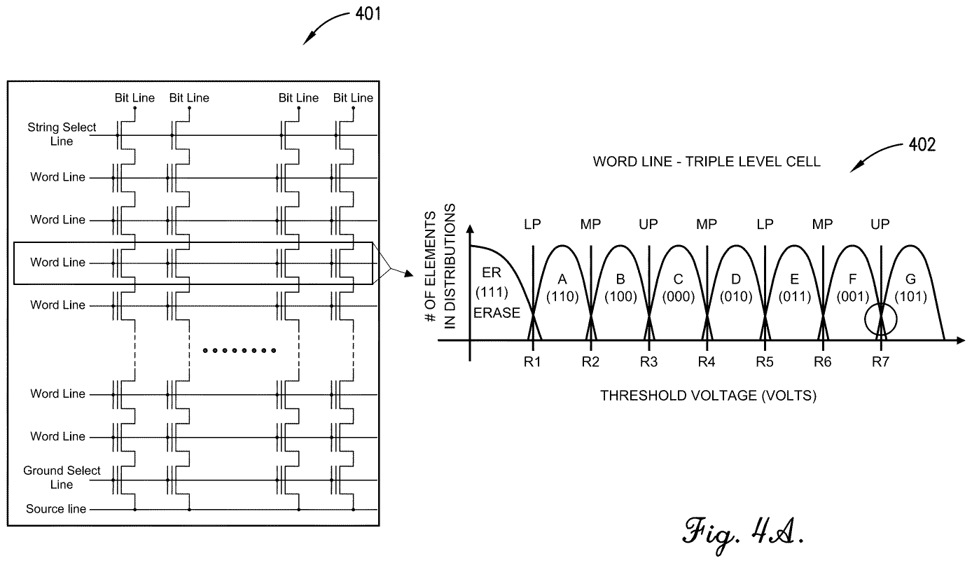

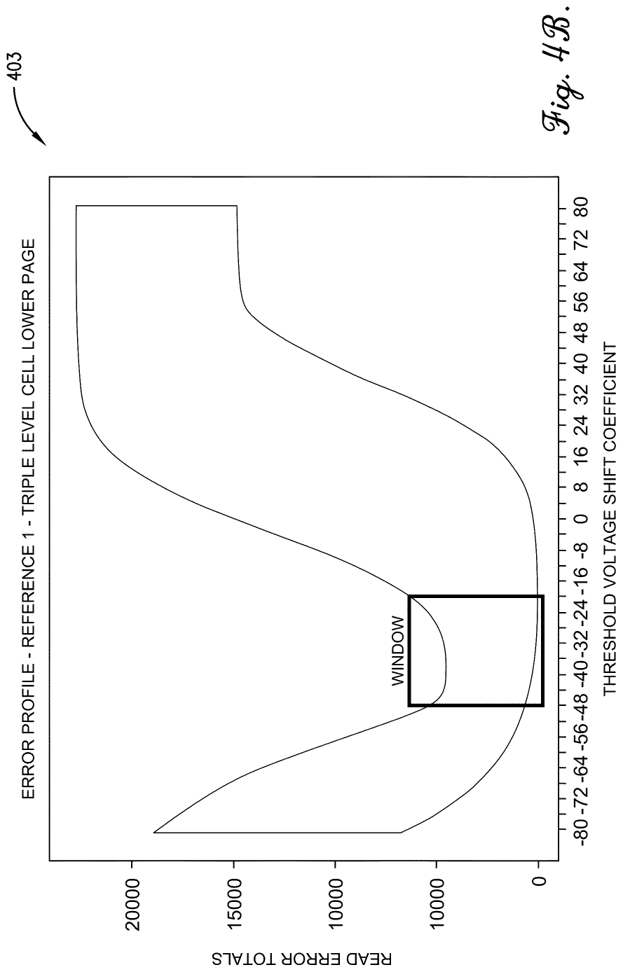

Referring to FIG. 4A, to the left of the figure is a schematic structural diagram 401 of a block of one (1) NVM media 116. The diagram 401 is substantially similar to the diagram 301 except that a plurality of TLC memory cells is bounded by a box. To the right in FIG. 4A is a first plot 402 of a number of elements in a distribution versus the threshold voltage applied to the WL for the plurality of TLC memory cells: in the LP position with the reference R1 and a fifth reference (“R5”); a middle page (“MP”) position with a second reference (“R2”), a fourth reference (“R4”) and a sixth reference (“R6”); and an upper page (“UP”) position with a third reference (“R3”) and a seventh reference (“R7”).

The TLC WL is connected to a plurality of cells. Each of the plurality of cells may store three (3) data bits. The cells may be in one of eight (8) different programming states according to values of each of the three (3) data bits. A lowest state of the programming states may correspond to an erased state. The erased state may be associated with a lowest threshold voltage of the TLC WL. The data bit values corresponding to the erased state may be 111. A highest state of the programming states may correspond to a G-state. The G-state may correspond to a highest threshold voltage of the TLC WL. The remaining states may correspond to A, B, C, D, E, and F-states and may be associated with threshold voltages between the erased state and the G-state. In various examples, the memory device may include WLs other than TLC WLs, such as SLC, MLC, QLC, PLC WLs, or combinations thereof. The SLC, MLC, QLC, PLC WLs, or combinations thereof, may be associated with corresponding programming states, including respective highest and lowest states. The SLC, MLC, QLC, PLC WLs, or combinations thereof, may be programmed to the respective highest states to securely erase or corrupt data in the corresponding WL.

In various examples, the WLs containing combinations of SLC, MLC, TLC, QLC, and/or PLC cells are in the same block of NVM media 116. Wherever combinations of SLC, MLC, TLC, QLC, and/or PLC cells are in the same block, one or more WLs connected to lower-capacity cells (e.g., SLC WLs in a block also including TLC WLs) may be programmed to store dummy data and may be read (e.g., in connection with a read request and/or normal background operation(s) and/or patrol read operation(s)) to generate input data (i.e., datasets) for ML model(s) discussed herein to determine optimal threshold voltages for reading higher-capacity cells. In various examples, generation of the input data or vector for the ML model(s), and/or the inference operations of the ML model(s), are triggered by output of one or more patrol read scan(s), such as where results of the scan(s) preliminarily indicate a read voltage offset greater than a threshold.

Referring to FIG. 4B, a second plot 403 of a number of read error totals versus a threshold voltage shift coefficient for a plurality of TLC memory cells of the NVM media 116 is shown. The plot 403 is similar to the plot 303 and includes a plurality of curved lines that, when plotted on the same graph in combination, form a variable width curve having the outlined boundaries (although the individual curved lines are not shown). Each curved line represents a plot of a total number of read errors versus the threshold voltage shift coefficient, from which the threshold voltage is determined. The threshold voltage is applied to a respective one of a plurality of WLs, such as the WLs shown in the diagram 401, that is electrically connected to a plurality of TLC memory cells. The WLs and the TLC memory cells to which they are connected may include a plurality of pages positioned in a plurality of blocks and on a plurality of dies of memory storage.

The data shown in the plot 403 is created by applying a voltage source, i.e., a power supply, to each of the plurality of WLs. The voltage applied to each WL may be swept, or varied, from a first threshold voltage to a second threshold voltage. For example, as shown in FIG. 4B, the voltage applied to each WL is swept from the first threshold voltage to the second threshold voltage using a threshold voltage shift coefficient that varies from approximately −80 to approximately 80, or vice versa. At a certain increment of the threshold voltage shift coefficient, say approximately two (2) or four (4), the total number of read errors for each WL is recorded. Given that the NVM media 116 may comprise hundreds or thousands of WLs, for each increment of the threshold voltage shift coefficient, a total of hundreds or thousands of read errors may be recorded. There is variability in the read error totals recorded across the different WLs which gives the curve of the displayed data its width. As an example, for a threshold voltage shift coefficient of approximately −20, the read error totals range from approximately zero (0) to approximately 7,000 according to the page of the TLC memory cells to which a respective one of the WLs is connected. That is, one of the pages of TLC memory cells may yield a read error total of approximately zero (0), while another of the pages of TLC memory cells may yield a read error total of approximately 7,000.

The plot 403 includes data recorded for the reference R7 of the TLC memory cells. Data may also be recorded for the references R1-R6, and a respective one of a plurality of plots may be generated for the other references. The read error totals recorded may include a plurality of read disturb errors recorded during a plurality of P/E cycles or a plurality of data retention errors recorded during the plurality of P/E cycles.

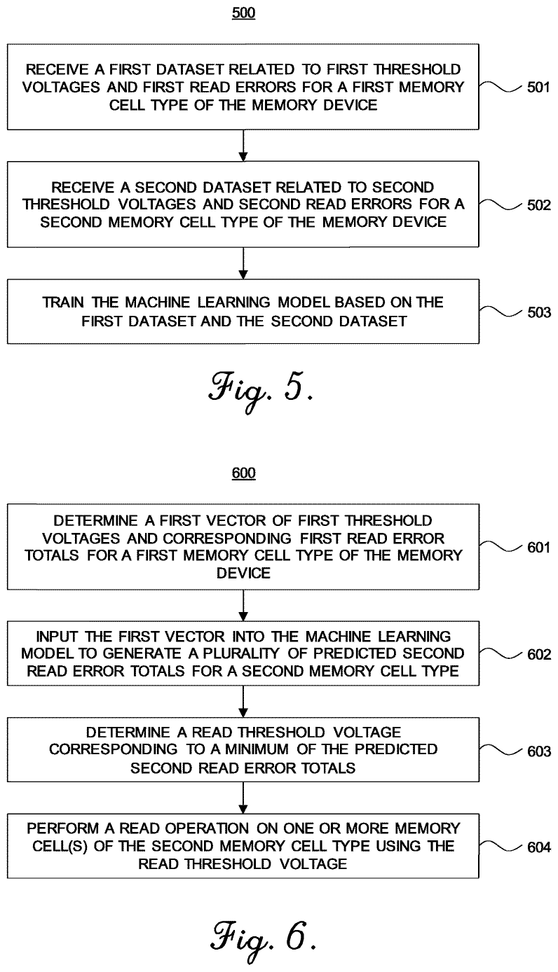

With reference to FIGS. 3A, 3B, 4A, and 4B, one or more ML model(s) is/are trained using the following example method 500 according to the blocks shown in FIG. 5. The method 500 may be performed when the data storage system 104 is offline and not executing normal operations. One of ordinary skill will appreciate that the training may be performed by a different computing device, on data obtained from a different, though similarly-constructed, memory device, or both, without departing from the spirit of the present disclosure.

Referring to block 501, a first dataset is received. The first dataset includes a plurality of threshold voltages and the corresponding read error totals at a reference for a plurality of memory cells having a type and corresponding capacity. In an example, the read error totals are for reference R1 and the memory cells are SLC memory cells of the NVM media 116 having a one (1) bit capacity. An example of data used to form such a first dataset is shown as a plot 303 in FIG. 3B of read error totals versus threshold voltage shift coefficients, from which threshold voltages are determined. The threshold voltages are applied to each of a plurality of WLs electrically connected to a plurality of SLC memory cells. The WLs and the SLC memory cells to which they are connected may include a plurality of pages positioned in a plurality of blocks and on a plurality of dies of memory storage. The plot 303 includes a plurality of curved lines that, when plotted on the same graph in combination, form a variable width curve, the boundaries of which are outlined (although the individual curved lines are not shown). Each curved line represents a plot of a total number of read errors versus the threshold voltage shift coefficient, from which the threshold voltage is determined. The threshold voltage is applied to a respective one of a plurality of WLs, such as the WLs shown in the diagram 301, that is electrically connected to a plurality of SLC memory cells.

The read error totals may include a plurality of read disturb errors recorded during a plurality of P/E cycles, a plurality of data retention errors recorded during the plurality of P/E cycles, or a combination of both. The first dataset may be created by applying a voltage source to each of the plurality of WLs. The voltage applied to each WL may be swept, or varied, from a first threshold voltage to a second threshold voltage. For example, as shown in FIG. 3B, the voltage applied to each WL is swept from the first threshold voltage to the second threshold voltage using a threshold voltage shift coefficient that varies from approximately −40 to approximately 120, or vice versa. At a certain increment of threshold voltage shift coefficient, say approximately two (2) or four (4), the total number of read errors for each WL is recorded. Given that the NVM media 116 may comprise hundreds or thousands of WLs, for each increment of the threshold voltage shift coefficient, a total of hundreds or thousands of read errors may be recorded.

Referring to block 502, a second dataset is received. The second dataset includes a plurality of threshold voltages and the corresponding read error totals at a reference for a plurality of memory cells having a second type and a corresponding second capacity. In an example, the read error totals are for reference R7 and the memory cells are TLC memory cells of the NVM media 116 having a three (3) bit capacity. An example of data used to form such a second dataset is shown as a plot 403 in FIG. 4B of read error totals versus threshold voltage shift coefficients, from which threshold voltages are determined. The threshold voltages are applied to each of a plurality of WLs electrically connected to a plurality of TLC memory cells. The WLs and the TLC memory cells to which they are connected may include a plurality of pages positioned in a plurality of blocks and on a plurality of dies of memory storage. The plot 403 includes a plurality of curved lines that, when plotted on the same graph in combination, form a variable width curve, the boundaries of which are outlined (although the individual curved lines are not shown). Each curved line represents a plot of a total number of read errors versus the threshold voltage shift coefficient, from which the threshold voltage is determined. The threshold voltage is applied to a respective one of a plurality of WLs, such as the WLs shown in the diagram 401, that is electrically connected to a plurality of TLC memory cells.

The read error totals may include a plurality of read disturb errors recorded during a plurality of P/E cycles, a plurality of data retention errors recorded during the plurality of P/E cycles, or a combination of both. The second dataset may be created by applying a voltage source to each of the plurality of WLs. The voltage applied to each WL may be swept, or varied, from a first threshold voltage to a second threshold voltage. For example, as shown in FIG. 4B, the voltage applied to each WL is swept from the first threshold voltage to the second threshold voltage using a threshold voltage shift coefficient that varies from approximately −80 to approximately 80, or vice versa. At a certain increment of threshold voltage shift coefficient, say approximately two (2) or four (4), the number of read errors for each WL is recorded. Given that the NVM media 116 may comprise hundreds or thousands of WLs, for each increment of the threshold voltage shift coefficient, a total of hundreds or thousands of read errors may be recorded.

It should be noted that the first dataset may represent threshold voltages applied to and resultant errors of WLs connected to memory cells of any type and corresponding capacity, and the second dataset may represent threshold voltages applied to and resultant errors of WLs connected to memory cells of any type and corresponding capacity, provided that the cells of the WLs of the second dataset have a higher capacity than those of the first dataset. Further, the reference associated with either dataset may vary. Still further, multiple second datasets—for example, associated with multiple different references and corresponding threshold voltage and error totals—may be retrieved for training with the first dataset without departing from the spirit of the present disclosure.

In various examples, a dataset may comprise datapoints which are averages of read error totals given by all or subsets of the WLs of the corresponding memory cell type at a given threshold voltage without departing from the spirit of the present disclosure.

Referring to block 503, the ML model is trained based on the first dataset and the second dataset. The training involves determining, or forming, a first vector and a second vector. The first vector includes data points, such as one or more threshold voltages and one or more corresponding read error totals, from the first dataset. For example, with reference to FIG. 3B, three (3) data points are selected, although a greater number of data points may be used. The data points are selected at intervals along the threshold voltage shift coefficient axis. In this example, there is an interval of twenty (20) between the data points. A larger or smaller interval could be utilized, or the interval may be different between consecutive data points. For each threshold voltage shift coefficient of the selected data points, the threshold voltage and the corresponding read error total for a particular WL, or the one or more WL(s) of a particular page, are identified. In the example shown in FIG. 3B, the first vector includes a first data point of the threshold voltage determined from a threshold voltage shift coefficient of 40 and 500 read errors, a second data point of the threshold voltage determined from a threshold voltage shift coefficient of 60 and 9,500 read errors, and a third data point of the threshold voltage determined from a threshold voltage shift coefficient of 80 and 33,000 read errors.

The second vector includes data points, such as one or more threshold voltages and one or more corresponding read error totals, from the second dataset such that one of the data points has a read error total value which is a minimum for the selected WL, or the one or more WL(s) of a particular page. For example, with reference to FIG. 4B, a window is identified in which the read error totals for a majority of the WLs are a minimum. For a particular WL, or the one or more WL(s) of a particular page, the minimum value of the read error totals is determined, and the corresponding threshold voltage shift coefficient and the determined threshold voltage, which may be considered a “target” threshold voltage shift coefficient and a “target” threshold voltage, respectively, are determined. A first set of data points for the second vector is determined by selecting a plurality of threshold voltage shift coefficients whose values are less than the target threshold voltage shift coefficient. The corresponding read error totals and threshold voltages are determined. A second set of data points for the second vector is determined by selecting a plurality of threshold voltage shift coefficients whose values are greater than the target threshold voltage shift coefficient. The corresponding read error totals and threshold voltages are determined. In various examples, the second vector may include nine (9) data points, that is, four (4) threshold voltages that are less than the target threshold voltage, along with the corresponding read error totals, the target threshold voltage and its corresponding read error total, and four (4) threshold voltages that are greater than the target threshold voltage, along with the corresponding read error totals. The pluralities of threshold voltages represented in the second vector may, for example, be selected using threshold voltage shift coefficients at regular intervals—such as five (5) or ten (10), without limitation—from the target threshold voltage shift coefficient.

The ML model is trained to develop a mathematical relationship between the first dataset and the second dataset by using the first vector as an input to the model and using the second vector as a target output of the model. In various examples, the ML model develops multiple such relationships by training independently or simultaneously on multiple corresponding second data sets, such as a plurality of second data sets each corresponding to a respective reference level needed to read multiple pages of a second memory cell type having a high capacity. The ML model may be trained using supervised learning techniques or unsupervised learning techniques, perhaps iteratively, in order to find a minimal difference between the predicted output of the ML model and the second vector, which is the target output.

The method 500 may be executed multiple times to create a plurality of ML models, with one for each memory cell type. For example, a first ML model may be created for the MLC memory cell type, a second ML model may be created for the TLC memory cell type, a third ML model may be created for the QLC memory cell type, and a fourth ML model may be created for the PLC memory cell type. In addition, for each memory cell type, a ML model may be created for each of the reference levels. For example, with reference to the plot 402 of FIG. 4A, the TLC memory cell type has seven (7) references of threshold voltages. Thus, the method 500 may be executed seven (7) times to create an ML model for each of the references of threshold voltages.

The method 500 may be executed offline within the scope of the present disclosure. For example, a first computing system (e.g., a computing system 200) may comprise a training device constructed as a storage system 104. The threshold voltages of the first and second datasets may be applied to WLs of the training device as discussed above in connection with the method 500 to generate the error totals of the first and second datasets. The first and second datasets may be retrieved by a second computing system (e.g., another computing system 200), which may be a model training system. The model training system may train the ML model(s) on the first and second datasets to develop relationships enabling the ML model(s) to predict optimal read threshold voltages (corresponding to low errors) for use on higher-capacity memory cells in devices similar to the training device which are in operation. The trained ML model(s) may be implemented in firmware installed on yet a third computing system (e.g., another computing system 200) constructed as a storage system 104 for use during operation for predicting optimal read thresholds as discussed in more detail below.

With reference to FIGS. 3A, 3B, 4A, and 4B, the ML model is used to determine a threshold voltage to be applied to a WL to read data from a memory device (e.g., memory device 114) using the following example method 600 according to the blocks shown in FIG. 6. The method 600 may be performed when the data storage system 104 is online and executing normal operations.

Referring to block 601, a first vector of first threshold voltages and corresponding first read error totals is determined for a first memory cell type of the memory device 114. The first memory cell type has a first capacity. For example, the first memory cell type may include an SLC memory cell, which is configured to store one (1) bit of data. In other examples, the first memory cell type may include the MLC memory cell configured to store two (2) bits of data, the TLC memory cell configured to store three (3) bits of data, or the QLC memory cell configured to store four (4) bits of data. Each first threshold voltage and corresponding first read error total (or corresponding average of read error totals) of the first vector may be considered a data point, wherein the data point is determined by recording a total number of read errors for a given threshold voltage applied to a particular WL (or plurality of WLs) connected to memory cells of the first memory cell type. The read error totals may include a plurality of read disturb errors recorded during a plurality of P/E cycles, a plurality of data retention errors recorded during the plurality of P/E cycles, or a combination of both. In various examples, the first vector may include three (3) data points.

Referring to block 602, the first vector is input into the ML model to generate a plurality of predictions. In various examples where the ML model is trained to correlate input threshold voltages and read error totals to predicted optimal target threshold voltage(s), the ML model may output such target threshold voltage(s) for use performing read operations on a second memory cell type of the memory device 114. The ML model may also or alternatively output predicted second read error totals for the second memory cell type of the memory device 114. Such predicted second read error totals may be input to a lookup table or algorithm or the like for translating same into corresponding optimal target threshold voltage(s) for one or more reference levels.

More particularly, the ML model is trained to have, possess, or implement a mathematical relationship between a first dataset and a second dataset. The first dataset includes a plurality of first threshold voltages and the corresponding first read error totals for a plurality of memory cells of the first memory cell type. An example of a plot of the first dataset is shown in FIG. 3B for SLC memory cells. The second dataset includes a plurality of second threshold voltages and the corresponding second read error totals for a plurality of memory cells of the second memory cell type, wherein the second memory cell type has a second capacity that is greater than the first capacity. An example of a plot of the second dataset is shown in FIG. 4B for TLC memory cells of the LP having reference R1. For a TLC memory cell, being positioned in other pages and having other reference voltages are possible. For example with reference to FIG. 4A, the TLC memory cell may be positioned in the LP and have reference voltages R1 and R5. The TLC memory cell may be positioned in the MP and have reference voltages R2, R4, and R6. The TLC memory cell may be positioned in the UP and have reference voltages R3 and R7.

After receiving the first vector as input, the ML model outputs a second vector which includes, in the latter example given above, a plurality of predicted second read error totals. In various examples, the predicted second read error totals refer to the second read error totals of the second dataset for a particular WL, or the one or more WL(s) of a particular page. Furthermore, given the training of the ML model, the predicted second read error totals refer to the second read error totals that are in the minima region within the window of FIG. 4B.

Referring to block 603, a read threshold voltage corresponding to a minimum of the predicted second read error totals is determined. In various examples provided above, the read threshold voltage is output by the ML model(s). In other examples, the minimum of the predicted second read error totals is determined and that value is used as the second read error total (for a particular WL, or the one or more WL(s) of a particular page) for determining the read threshold voltage. For example, the second read error total may be used to look up the corresponding second threshold voltage in the second dataset-which is the read threshold voltage.

Referring to block 604, a read operation is performed on one or more memory cell(s) of the second memory cell type using the read threshold voltage. Specifically, data is read from one or more memory cells of the second memory cell type by applying the read threshold voltage at a corresponding reference level to the WL connected to the one or more memory cells of the second type. As noted above, where the ML model is trained to output multiple second read error totals and/or read threshold voltages corresponding to multiple reference levels, such a read operation may include applying the multiple read threshold voltages at their respective reference levels for a given cell type.

The method 600 may be utilized with multiple ML models. That is, a respective one of a plurality of ML models may be created for each memory cell type. For example, a first ML model may be used for the MLC memory cell type, a second ML model may be used for the TLC memory cell type, a third ML model may be used for the QLC memory cell type, and a fourth ML model may be used for the PLC memory cell type. The appropriate ML model is utilized to determine the read threshold voltage for one or more memory cell(s) according to the memory cell type whose data is to be read. Thus, the first ML model is used for determining the read threshold voltage for data to be read from MLC memory cells, the second ML model is used for determining the read threshold voltage for data to be read from TLC memory cells, and so forth.

In addition, for each memory cell type, an ML model may be used for each of the reference levels. For example, with reference to the plot 402 of FIG. 4A, the TLC memory cell type has seven (7) references of threshold voltages. Thus, seven (7) ML models may be created and used for the references of threshold voltages for the TLC memory cell type. A single ML model for a single reference level may be created for each memory cell type.

Further, and particularly where output of a ML model is used to predict read voltage thresholds for multiple reference levels, a linear or non-linear offset may be utilized with the ML model(s) for a first reference level to modify the corresponding read threshold voltage for usage with the other reference levels. As an example, if one (1) ML model is created for the TLC memory cell type at a reference level of seven (7) R7, then the read threshold voltage, as determined in block 603 of the method 600, is adjusted according to a mathematical equation or arithmetic function. A read threshold voltage for a second reference level—say, the read threshold voltage for reference level R1—may be computed as the read threshold voltage for reference R7 plus x, where x is a variable. In another example, the read threshold voltage for reference level R1 may be computed as the read threshold voltage for reference R7 multiplied by x, where x is a variable. Other mathematical relationships may be used to compute read threshold voltages at other reference levels based on a read threshold voltage at an initial reference level within the scope of the present disclosure.

The accuracy of methods 500 and 600, i.e., training the ML model and using it to determine threshold voltages for reading data from memory cells, is given by the following equation:

$$Accuracy = \frac{\# ( Predicted - Measured == 0 ) + \# ( Predicted - Measured == \pm n )}{\#Measured Values}$$

In plain words, the accuracy is equal to the number of times the predicted values of the vector output by the ML model were within a tolerance range of the measured values divided by the number of measured values, wherein the vector output by the ML model includes n threshold voltage values that are less than the target threshold voltage and n threshold voltage values that are greater than the target threshold voltage. Using this metric, the accuracy of methods 500 and 600 may be determined. For example, in various trials, an accuracy of 97% or greater was achieved.

Throughout this specification, references to “one example”, “an example”, or “examples” mean that the feature or features being referred to are included in at least one example of the technology. Separate references to “one example”, “an example”, or “examples” in this description do not necessarily refer to the same example and are also not mutually exclusive unless so stated or except as will be readily apparent to those skilled in the art from the description, or a combination thereof. For example, a feature, structure, act, etc. described in one example may also be included in other examples, but is not necessarily included. Thus, the current technology can include a variety of combinations, integrations, or both, of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain examples are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In examples, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various examples, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering examples in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In examples in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some examples, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some examples, the processors may be located in a single location (e.g., within a home environment, an office environment or as a server farm), while in other examples the processors may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A computer-implemented method for training a machine learning model to determine a threshold voltage used to read data from a memory device, the computer-implemented method comprising:
receiving a first dataset related to first threshold voltages and first read error totals for a first memory cell type of the memory device, the first memory cell type having a first data storage capacity;
receiving a second dataset related to second threshold voltages and second read error totals for a second memory cell type of the memory device, the second memory cell type having a second data storage capacity which is greater than the first data storage capacity; and
training the machine learning model based on the first dataset and the second dataset, the trained machine learning model being configured to determine the threshold voltage for use with one or more memory cell(s) of the second memory cell type based on input data from one or more memory cell(s) of the first memory cell type.

2. The computer-implemented method of claim 1, comprising applying the first threshold voltages to one or more word line(s) of a training memory device, the one or more word line(s) connected to a plurality of memory cells of the first memory cell type, wherein the first read error totals each comprise a count of errors generated by the application of one of the first threshold voltages.

3. The computer-implemented method of claim 2, wherein the first read error totals include errors of one or both of read disturb or data retention types, and wherein the first read error totals are recorded over a plurality of program/erase cycles.

4. The computer-implemented method of claim 1, comprising applying the second threshold voltages to one or more word line(s) of the training memory device, the one or more word line(s) corresponding to a plurality of memory cells of the second memory cell type, wherein the second read error totals each comprise a count of errors generated by the application of one of the second threshold voltages.

5. The computer-implemented method of claim 4, wherein the second read error totals include errors of one or both of read disturb or data retention types, and wherein the second read error totals are recorded over a plurality of program/erase cycles.

6. The computer-implemented method of claim 1, further comprising the following, performed before the training of the machine learning model:
determining a first vector including a subset of the first threshold voltages and the corresponding first read error totals; and
determining a second vector including a subset of the second threshold voltages and the corresponding second read error totals, wherein the second vector includes a target second threshold voltage corresponding to one of the second read error totals which is a minimum of second read error totals.

7. The computer-implemented method of claim 6, wherein the second vector includes—
one or more second threshold voltages less than the target second threshold voltage and one or more corresponding second read error totals,
one or more second threshold voltages greater than the target second threshold voltage and one or more corresponding second read error totals.

8. The computer-implemented method of claim 6, wherein the training of the machine learning model includes developing one or more mathematical relationship(s) between the first dataset and the second dataset by using the first vector as an input to the machine learning model and the second vector as a targeted output of the machine learning model.

9. A computer-implemented method for using a machine learning model to determine a threshold voltage and using the threshold voltage to read data from a memory device, the computer-implemented method comprising:
determining a first vector of first threshold voltages and corresponding first read error totals for a first memory cell type of the memory device, the first memory cell type having a first capacity;
inputting the first vector into the machine learning model to generate a plurality of predicted second read error totals for a second memory cell type, the second memory cell type having a second capacity which is greater than the first capacity;
determining a read threshold voltage corresponding to a minimum of the predicted second read error totals; and
performing a read operation in the memory device on one or more memory cell(s) of the second memory cell type using the read threshold voltage.

10. The computer-implemented method of claim 9, wherein the first read error totals comprise counts of read errors generated by application of the first threshold voltages to one or more word line(s) of the memory device, the one or more word line(s) connected to memory cells of the first memory cell type.

11. The computer-implemented method of claim 9, wherein the predicted second read error totals match a subset of a plurality of second read error totals from a second memory cell type dataset, the second memory cell type dataset including a plurality of second threshold voltages applied to one or more word line(s) connected to a plurality of memory cells of the second memory cell type, wherein the second read error totals each comprise a count of errors generated by the application of one of the second threshold voltages.

12. The computer-implemented method of claim 11, wherein the second read error totals include errors of one or both of read disturb or data retention types, and wherein the second read error totals are recorded over a plurality of program/erase cycles.

13. The computer-implemented method of claim 11, wherein the read threshold voltage corresponds in the second memory cell type dataset to the minimum of the predicted second read error totals.

14. The computer-implemented method of claim 11, wherein the machine learning model is trained to generate the predicted second read error totals according to a mathematical relationship between the second memory cell type dataset and a first memory cell type dataset.

15. The computer-implemented method of claim 14, wherein the first memory cell type dataset includes a plurality of first threshold voltages applied to one or more word line(s) connected to a plurality of memory cells of the first memory cell type, and a plurality of first read error totals, wherein the first read error totals each comprise a count of errors generated by the application of one of the first threshold voltages.

16. The computer-implemented method of claim 15, wherein the first read errors include errors of one or both of read disturb or data retention types, and wherein the first read error totals are recorded over a plurality of program/erase cycles.

17. Non-transitory computer readable media having instructions stored thereon, that when executed by at least one processor, cause the at least one processor to:
receive a first dataset related to first threshold voltages and first read error totals for a first memory cell type of the memory device, the first memory cell type having a first data storage capacity;
receive a second dataset related to second threshold voltages and second read error totals for a second memory cell type of the memory device, the second memory cell type having a second data storage capacity which is greater than the first data storage capacity; and
train the machine learning model based on the first dataset and the second dataset, the trained machine learning model being configured to determine the threshold voltage for use with one or more memory cell(s) of the second memory cell type based on input data from one or more memory cell(s) of the first memory cell type.

18. The non-transitory computer readable media of claim 17, wherein the instructions, when executed by the at least one processor, further cause the at least one processor to apply the first threshold voltages to one or more word line(s) of a training memory device, the one or more word line(s) corresponding to a plurality of memory cells of the first memory cell type, wherein the first read error totals each comprise a count of errors generated by the application of one of the first threshold voltages, the first read error totals including errors of one or both of read disturb or data retention types, and wherein the first read error totals are recorded over a plurality of program/erase cycles.

19. The non-transitory computer readable media of claim 17, wherein the instructions, when executed by the at least one processor, further cause the at least one processor to apply the second threshold voltages to one or more word line(s) of the training memory device, the one or more word line(s) corresponding to a plurality of memory cells of the second memory cell type, wherein the second read error totals each comprise a count of errors generated by the application of one of the second threshold voltages, the second read error totals including errors of one or both of read disturb or data retention types, and wherein the second read error totals are recorded over a plurality of program/erase cycles.

20. The non-transitory computer readable media of claim 17, wherein the instructions, when executed by the at least one processor, further cause the at least one processor to—
determine a first vector including a subset of the first threshold voltages and the corresponding first read error totals; and
determine a second vector including a subset of the second threshold voltages and the corresponding second read error totals, wherein the second vector includes a target second threshold voltage corresponding to one of the second read error totals which is a minimum of second read error totals.
